(19) United States
(12) Patent Application Publication
(10) Pub. No.: US 2024/0230232 A1
(43) Pub. Date: Jul. 11, 2024

(54) GAS CONTROL SYSTEM FOR REFLOW FURNACE AND REFLOW FURNACE

(71) Applicant: Illinois Tool Works Inc., Glenview, IL (US)

(72) Inventors: Yuexin Chen, Glenview, IL (US); Yuwei Wang, Glenview, IL (US); Dong Zhang, Glenview, IL (US)

(21) Appl. No.: 18/560,291

(22) PCT Filed: May 20, 2022
(86) PCT No.: PCT/US2022/030185

§ 371 Date: Nov. 10, 2023

(30) Foreign Application Priority Data
May 24, 2021 (CN) 202110562988.0

(51) Int. Cl. F27B 9/30; F27B 9/04; F27B 17/00; F27D 7/06

(52) U.S. Cl. CPC F27B 9/3005; F27B 9/045; F27B 17/0083; F27D 7/06

(57) ABSTRACT

The present application discloses a gas control system for a reflow oven, a hearth thereof comprising a preheating zone, a peak zone and a cooling zone. The gas control system comprises: an oxygen detection apparatus, a first valve apparatus, a second valve apparatus and a controller. The controller is configured to control the degree of opening of the first valve apparatus and/or the second valve apparatus when the oxygen concentration detected by the oxygen detection apparatus does not satisfy a preset value, in order to enable the oxygen concentration in the peak zone to satisfy the preset value by adjusting the flow rate of working gas and/or air inputted into the peak zone. The gas control system and reflow oven of the present application first perform rough adjustment of gas in the hearth, such that the oxygen concentration in the hearth is substantially close to the preset value. The oxygen concentration in the peak zone of the hearth is then adjusted precisely by means of the first valve apparatus and second valve apparatus. Thus, even though the amount of oxygen in air entering the hearth is indeterminate, the oxygen concentration of the peak zone will not be affected, so the quality of circuit board soldering can be increased in a stable fashion.

### TECHNICAL FIELD

The present application relates to the field of reflow ovens, in particular to a gas control system for a reflow oven, and a reflow oven.

### BACKGROUND ART

In the course of printed circuit board production, electronic components are generally mounted on the circuit board by a process known as “reflow soldering”. In a typical reflow soldering process, solder paste (e.g. tin paste) is deposited in selected regions on the circuit board, and conductive wires of one or more electronic components are inserted into the deposited solder paste. The circuit board is then passed through a reflow oven, in which the solder paste reflows (i.e. is heated to melting or reflow temperature) in a heating region, before cooling in a cooling region, to connect the conductive wires of the electronic components to the circuit board electrically and mechanically. The term “circuit board” used here includes substrate assemblies for electronic components of any type, e.g. wafer substrates.

Inside the reflow oven, air or a substantially inert gas (such as nitrogen) is generally used as a working gas, which fills a hearth of the reflow oven. The circuit board to be soldered undergoes soldering in the working gas when conveyed through the hearth by means of a conveying apparatus. In the case of a reflow oven using a substantially inert gas as the working gas, it is generally necessary to keep the concentration of oxygen in the working gas in the hearth within a certain range by means of a gas control system, for circuit boards with different process requirements.

### SUMMARY OF THE INVENTION

In a first aspect, an objective of the present application is to provide a gas control system for a reflow oven, a hearth of the reflow oven containing a gas, the gas comprising oxygen and a working gas, and the hearth comprising a preheating zone, a peak zone and a cooling zone. The gas control system comprises: an oxygen detection apparatus, the oxygen detection apparatus being configured to detect the oxygen concentration in the peak zone; a first valve apparatus, the first valve apparatus being configured to fluidly connect a working gas source to the peak zone of the hearth in a controllable fashion; a second valve apparatus, the second valve apparatus being configured to fluidly connect an air source to the peak zone of the hearth in a controllable fashion; and a controller, the controller being in communicative connection with the oxygen detection apparatus, the first valve apparatus and the second valve apparatus; and the controller being configured to control the degree of opening of the first valve apparatus and/or the second valve apparatus when the oxygen concentration detected by the oxygen detection apparatus does not satisfy a preset value, in order to enable the oxygen concentration in the peak zone to satisfy the preset value by adjusting the flow rate of working gas and/or air inputted into the peak zone of the hearth.

According to the first aspect, the gas control system comprises a mixing duct, the mixing duct comprising a first inlet, a second inlet and at least one outlet, the working gas source being in fluid communication with the first inlet via the first valve apparatus, the air source being in fluid communication with the second inlet via the second valve apparatus, and the at least one outlet being in fluid communication with the peak zone.

According to the first aspect, the peak zone comprises three secondary peak zones, the three secondary peak zones comprising a middle secondary peak zone located in the middle and two side secondary peak zones located at two sides of the middle secondary peak zone; the oxygen detection apparatus is configured to detect the oxygen concentration in the middle secondary peak zone; and the at least one outlet comprises two outlets, the two outlets being in fluid communication with the two side secondary peak zones respectively.

According to the first aspect, the gas control system further comprises: a third valve apparatus, the third valve apparatus being configured to fluidly connect the working gas source to the preheating zone of the hearth; the degree of opening of the third valve apparatus remaining unchanged during operation of the reflow oven.

According to the first aspect, the preheating zone comprises multiple secondary preheating zones, and the working gas source is controllably in fluid communication with the secondary preheating zone that is second-furthest from the peak zone via the third valve apparatus.

According to the first aspect, the gas control system further comprises: a fourth valve apparatus, the fourth valve apparatus being configured to fluidly connect the working gas source to the cooling zone of the hearth; the degree of opening of the fourth valve apparatus being determined according to the preset value.

According to the first aspect, the cooling zone comprises multiple secondary cooling zones, and the working gas source is controllably in fluid communication with the secondary cooling zone that is second-furthest from the peak zone via the fourth valve apparatus.

According to the first aspect, the controller is configured to: determine an adjustment range according to the preset value of oxygen concentration; increase the degree of opening of the first valve apparatus when the oxygen concentration detected by the oxygen detection apparatus is greater than the maximum value of the adjustment range, to enable the oxygen concentration to reach the adjustment preset range by increasing the flow rate of working gas inputted into the peak zone of the hearth; increase the degree of opening of the second valve apparatus when the oxygen concentration detected by the oxygen detection apparatus is less than the minimum value of the adjustment range, to enable the oxygen concentration to reach the adjustment preset range by increasing the flow rate of oxygen inputted into the peak zone of the hearth; and adjust the degrees of opening of the first valve apparatus and the second valve apparatus when the oxygen concentration detected by the oxygen detection apparatus is within the adjustment preset range, so that the oxygen concentration in the peak zone satisfies the preset value.

According to the first aspect, the first valve apparatus, the second valve apparatus, the third valve apparatus and the fourth valve apparatus are flow control valves.

In a second aspect, an objective of the present application is to provide a reflow oven, comprising: a hearth, the hearth comprising a preheating zone, a peak zone and a cooling zone, and the hearth containing a gas, the gas comprising oxygen and a working gas; and the gas control system as described in the first aspect.

### BRIEF DESCRIPTION OF THE DRAWINGS

FIG. 1A is a schematic drawing of a reflow oven according to an embodiment of the present application.

FIG. 1B is a diagram of gas flow directions in the gas control system of the reflow oven shown in FIG. 1A.

FIG. 2 is a schematic drawing of the controller in FIG. 1A.

FIG. 3 is a schematic diagram of the steps of a gas control method for the reflow oven shown in FIG. 1A.

### DETAILED DESCRIPTION OF EMBODIMENTS

Various particular embodiments of the present application are described below with reference to the drawings, which form part of this specification. It should be understood that although terms indicating direction, such as “front”, “rear”, “up”, “down”, “left”, “right”, “top”, “bottom”, “inner” and “outer” are used in the present application to describe various exemplary structural parts and elements of the present application, these terms are used here solely to facilitate explanation, and determined on the basis of the exemplary orientations shown in the drawings. Since the embodiments disclosed in the present application may be arranged in different directions, these terms indicating direction are merely illustrative and should not be regarded as limiting.

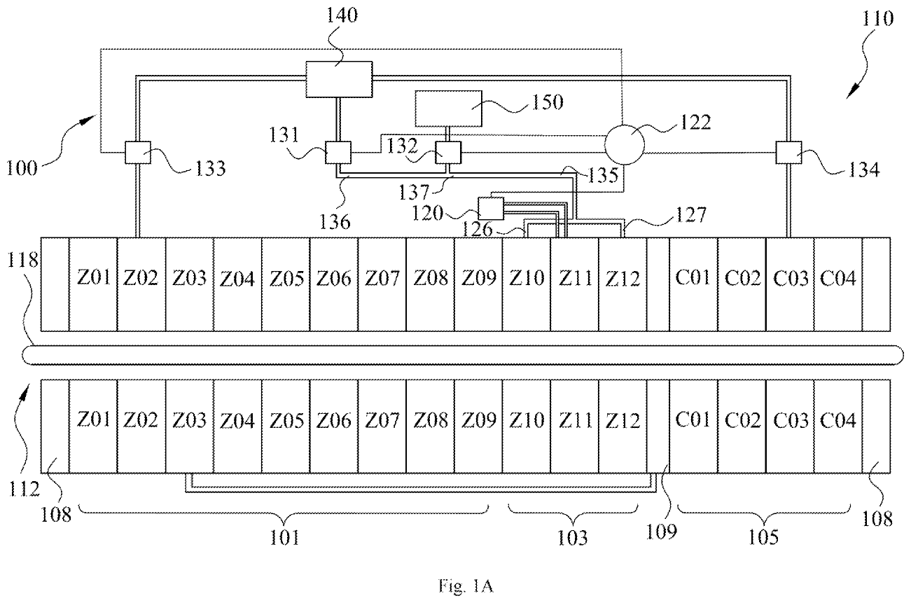

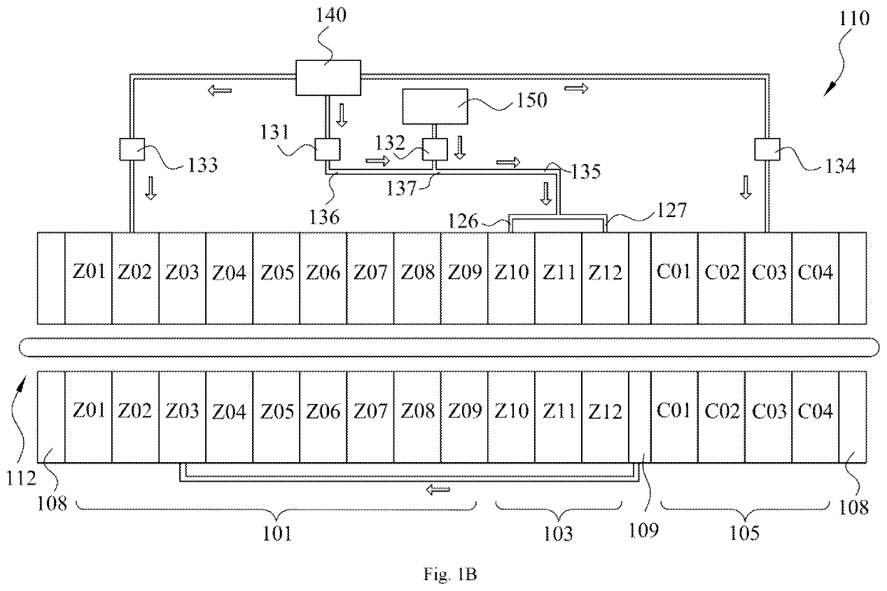

FIG. 1A is a simplified schematic drawing of an embodiment of the reflow oven of the present application, showing a view from one side of the reflow oven. FIG. 1B is a diagram of gas flow directions in the gas control system of the reflow oven. As shown in FIGS. 1A and 1B, the reflow oven 110 comprises a hearth 112 and a gas control system 100. The hearth 112 comprises a preheating zone 101, a peak zone 103 and a cooling zone 105, arranged in sequence in the length direction of the hearth 112, and in fluid communication with each other. The gas control system 100 is in fluid communication with the hearth 112, to adjust the working gas atmosphere in the hearth 112. The reflow oven 110 further comprises a conveying apparatus 118. The conveying apparatus 118 runs through the hearth 112 in the length direction of the hearth 112, being used to feed a circuit board to be processed into the hearth 112 from the left end of the hearth 112, and after sequential processing in the preheating zone 101, peak zone 103 and cooling zone 105, output the processed circuit board from the right end of the hearth 112. When soldering certain types of circuit board, the reflow oven needs to use a working gas which is principally an inert gas (e.g. nitrogen). A description is given below in the case where the working gas is principally nitrogen. It must be explained that FIGS. 1A and 1B show views from one side of the reflow oven 110, wherein, to facilitate description of the reflow oven 110, a housing used to cover front and rear sides of the hearth 112 has been removed in FIG. 1.

Heating apparatuses (not shown in the figures) are provided in the preheating zone 101 and the peak zone 103. In the embodiment shown in FIG. 1A, the preheating zone 101 comprises nine secondary preheating zones Z01-Z09, and the peak zone 103 comprises three secondary peak zones Z10-Z12. The secondary preheating zones Z01-Z09 and secondary peak zones Z10-Z12 are connected consecutively with gradually increasing temperature. “Connected consecutively” means that the secondary regions are sequentially arranged in the order of their sequence numbers. For example, the secondary peak zones comprise a middle secondary peak zone Z11 and side peak zones Z10 and Z12 located at two sides of the middle secondary peak zone Z11, the side peak zone Z10 being located between the secondary preheating zone Z09 and the middle secondary peak zone Z11. In the preheating zone 101, the circuit board is heated, and some of the flux in the solder paste distributed on the circuit board will vaporize. The temperature of the peak zone 103 is higher than that of the preheating zone 101, and the solder paste melts completely in the peak zone 103. The peak zone 103 is also a higher-temperature region in which VOCs (e.g. resin or turpentine in the flux) will vaporize.

A cooling apparatus (not shown in the figures) is provided in the cooling zone 105. In the embodiment shown in FIG. 1A, the cooling zone 105 comprises four secondary cooling zones C01-C04, which are also sequentially arranged in the order of their sequence numbers. Once the circuit board has been conveyed into the cooling zone 105 from the peak zone 103, the solder paste is cooled and hardens in soldering regions of the circuit board, thereby connecting electronic components to the circuit board. It is worth noting that the numbers of secondary regions in the preheating zone 101, the peak zone 103 and the cooling zone 105 of the reflow oven are not limited to the embodiment shown in FIGS. 1A and 1B, and can vary according to the product to be soldered and different soldering processes.

A connecting region between the side peak zone Z12 of the peak zone 103 and the secondary cooling zone C01 of the cooling zone 105 is provided with a separating gas discharge zone 109. The separation gas discharge zone 109 can extract or discharge gas from the hearth 112. After being cooled and filtered, the gas extracted from the separating gas discharge zone 109 can be conveyed back into the lower-temperature preheating zone 101 in the hearth 112, so as to block or reduce the entry of gas containing volatile pollutants into the cooling zone 105 from the peak zone 103. In addition, by extracting or discharging gas from the hearth 112, the separating gas discharge zone 109 can also be used as a temperature barrier region, isolating the high-temperature peak zone 103 from the low-temperature cooling zone 105. In this embodiment, the reflow oven 110 is also equipped with a gas discharge apparatus (not shown in the figures), for discharging gas containing volatile pollutants from the hearth 112. The gas discharge apparatus is generally connected in a higher-temperature region of the reflow oven 110, such as the peak zone 103 or separating gas discharge zone 109.

The reflow oven 110 of the present application uses a working gas consisting mainly of nitrogen, but the working gas also includes oxygen, the content thereof being controlled within a certain range. The reflow oven 110 further comprises gas separation zones 108 located at the left end and right end of the hearth 112 respectively. The gas separation zones 108 are used for supplying nitrogen towards the hearth 112 and thereby forming nitrogen curtains, by means of which it is possible to prevent air in the external environment from entering the hearth 112. When the reflow oven 110 is in an operational state of processing circuit boards, the gas discharge apparatus will also remain in an operational state at all times, in order to maintain the cleanliness of gas in the hearth 112. In this process, it is further necessary to continuously input clean nitrogen and/or air into the hearth 112, in order to maintain the working atmosphere required by the hearth 112.

The reflow oven 110 of the present application is further equipped with the gas control system 100, for adjusting the concentration of oxygen in the hearth 112 by adjusting the flow rate of nitrogen and/or air inputted into the hearth 112, so that the oxygen concentration reaches the level required by a specific soldering process in the reflow oven.

Continuing to refer to FIGS. 1A and 1B, the gas control system 100 comprises an oxygen detection apparatus 120, a valve apparatus 133 (i.e. a third valve apparatus 133) and a valve apparatus 134 (i.e. a fourth valve apparatus 134), and a controller 122. The oxygen detection apparatus 120 is in contact with gas in the hearth 112, and is used to detect the oxygen concentration in the hearth 112. Specifically, the oxygen detection apparatus 120 is used to detect the oxygen concentration in the peak zone 103 of the hearth 112. As an example, the oxygen detection apparatus 120 is configured to detect the oxygen concentration in the middle secondary peak zone Z11. The oxygen detection apparatus 120 is configured to supply an oxygen concentration signal to the controller 122, the oxygen concentration signal reflecting an actually detected value Dv of oxygen concentration.

Corresponding to an oxygen concentration demand of a specific soldering process, the present application presets a specific oxygen concentration preset value Tv and stores it in the controller 122. The controller 122 can identify the preset value Tv, obtains an adjustment range Rvmin-Rvmax close to the preset value Tv, and compares the actually detected value Dv reflected by the oxygen concentration signal generated by the oxygen detection apparatus 120 with the adjustment range Rvmin-Rvmax. If the actually detected value Dv is greater than the maximum value Rvmax of the adjustment range Rvmin-Rvmax, this indicates that the actual oxygen concentration is too high, and the actual nitrogen concentration is too low; if the actually detected value Dv is less than the minimum value Rvmin of the adjustment range Rvmin-Rvmax, this indicates that the actual oxygen concentration is too low, and the actual nitrogen concentration is too high.

The third valve apparatus 133 and fourth valve apparatus 134 are used to fluidly connect a nitrogen source 140 (i.e. a working gas source 140) to the preheating zone 101 and cooling zone 105 of the hearth 112 respectively in a controllable fashion, in order to input nitrogen into the hearth 112. In this embodiment, the working gas source 140 is in fluid communication with the secondary preheating zone Z02 (i.e. the secondary preheating zone that is second-furthest from the peak zone 103) via the third valve apparatus 133. In addition, the working gas source 140 is in fluid communication with the secondary cooling zone C03 (i.e. the secondary cooling zone that is second-furthest from the peak zone 103) via the fourth valve apparatus 134. The controller 122 controls the degree of opening V3 of the third valve apparatus 133 to remain unchanged during operation of the reflow oven 110; for example, the degree of opening of the third valve apparatus 133 is kept at 10%. In addition, the controller 122 controls the degree of opening V4 of the fourth valve apparatus 134 according to the preset value Tv of oxygen concentration; for example, when the preset value of oxygen concentration is 300-500 ppm, the degree of opening V4 of the fourth valve apparatus 134 may be set at 70%. The degree of opening of the valve apparatus means the degree to which the valve apparatus is opened, between 0 and 100%; for example, a degree of opening of 0 means that the valve apparatus is closed, and a degree of opening of 100% means that the valve apparatus is completely open. The oxygen concentration in the hearth 112 can be kept substantially within a certain range close to the preset value Tv of oxygen concentration by means of the third valve apparatus 133 and fourth valve apparatus 134.

Once nitrogen is inputted into the secondary preheating zone Z02 of the hearth 112 via the third valve apparatus 133, one portion of the nitrogen flows towards the secondary preheating zone Z01 close to the hearth inlet and out of the hearth 112, to prevent a portion of air from entering the hearth 112, and another portion of the nitrogen flows towards the peak zone 103, to take part in gas circulation in the interior of the hearth 112. Similarly, once nitrogen is inputted into the secondary cooling zone C03 of the hearth 112 via the fourth valve apparatus 134, one portion of the nitrogen flows towards the secondary cooling zone C04 close to the hearth outlet and out of the hearth 112, to prevent a portion of air from entering the hearth 112, and another portion of the nitrogen flows towards the secondary cooling zone C01, to take part in gas circulation in the interior of the hearth 112.

In the course of soldering, the gas extracted from the separating gas discharge zone 109 will also return to the preheating zone 101 of the hearth 112; consequently, the gas concentration inside the hearth 112 can substantially attain dynamic stability. Thus, the degree of opening V3 of the third valve apparatus 133 can remain unchanged during operation of the reflow oven 110, and it is only necessary to set the degree of opening V4 of the fourth valve apparatus 134 according to the preset value Tv of oxygen concentration in order to enable the oxygen concentration inside the hearth 112 to substantially meet requirements. In addition, in general, the degree of opening V3 of the third valve apparatus 133 is less than the degree of opening V4 of the fourth valve apparatus 134.

Still as shown in FIGS. 1A and 1B, the gas control system 100 further comprises a valve apparatus 131 (i.e. a first valve apparatus 131) and a valve apparatus 132 (i.e. a second valve apparatus 132). The first valve apparatus 131 and second valve apparatus 132 are used to fluidly connect the working gas source 140 and an air source 150 respectively to the peak zone 103 of the hearth 112 in a controllable fashion, in order to input nitrogen and/or air into the peak zone 103 of the hearth 112. The controller 122 is used to adjust in real time the degree of opening V1 of the first valve apparatus 131 and/or the degree of opening V2 of the second valve apparatus 132 according to the preset value Tv of oxygen concentration and the detected value Dv of oxygen concentration, in order to adjust the flow rate of nitrogen and/or air inputted into the hearth 112. The oxygen concentration in the peak zone 103 of the hearth 112 can thereby be precisely controlled so as to be close to the preset value Tv, e.g. within the adjustment range Rvmin-Rvmax.

As an example, the first valve apparatus 131 and second valve apparatus 132 are configured such that nitrogen and/or air first pass through a common mixing duct 135 and are then inputted into the side peak zones Z10 and Z12. In this example, the mixing duct 135 has a first inlet 136, a second inlet 137, a first outlet 126 and a second outlet 127, wherein the working gas source 140 is in fluid communication with the first inlet 136 via the first valve apparatus 131, and the air source 150 is in fluid communication with the second inlet 137 via the second valve apparatus 132. The first outlet 126 is in fluid communication with the side peak zone Z10, and the second outlet 127 is in fluid communication with the side peak zone Z12. Thus, nitrogen and/or air can be inputted into the mixing duct 135 via the first valve apparatus 131 and/or the second valve apparatus 132 respectively, and after mixing in the mixing duct 135, are inputted into the side peak zones Z10 and Z12 separately. The expression “and/or” above means that when the degrees of opening of the first valve apparatus 131 and second valve apparatus 132 are both not 0, nitrogen and air can first mix in the mixing duct 135 and then be inputted into the different secondary peak zones in the hearth. When the degree of opening of one of the first valve apparatus 131 and second valve apparatus 132 is 0, the gas control system 100 only inputs one of nitrogen or air to the peak zone 103, such that the nitrogen or air first passes through the mixing duct 135 and is then inputted into the different secondary peak zones in the hearth separately.

As the conveying apparatus 118 conveys circuit boards into or out of the hearth 112, a relatively small amount of air from the external environment will inevitably enter or leave the hearth 112 together with the conveying apparatus and circuit boards, therefore the working gas in the hearth 112 will always contain an indeterminate amount of oxygen. Different soldering processes have different requirements for the oxygen concentration level in the hearth 112, generally 0-5000 ppm (parts per million). Moreover, within the reflow oven 110, the temperature is highest in the peak zone 103, so this is a region which affects soldering quality to a greater extent in the soldering process. Thus, it is desired that the oxygen concentration in the hearth 112, especially the oxygen concentration in the peak zone 103, can be kept close the value required by a specific soldering process, e.g. within the adjustment range.

In some existing gas control systems, the oxygen concentration in the hearth is generally controlled by continuously replenishing nitrogen in the hearth. When the oxygen concentration in the hearth is high, it is also possible to reduce the oxygen concentration by inputting nitrogen into the hearth. However, when the oxygen concentration in the hearth is low, all that can be done is to wait for air carried by the conveying apparatus and circuit boards to increase the oxygen concentration. Not only does this result in late adjustment, the oxygen concentration is also difficult to control, and this affects the quality of circuit board soldering.

In the gas control system of the present application, based on the detected oxygen concentration, the oxygen concentration in the peak zone 103 is adjusted in real time by inputting nitrogen and/or air directly to the peak zone 103, thus enabling the oxygen concentration to remain close to the required preset value Tv, e.g. within the adjustment range Rvmin-Rvmax. For example, when the detected oxygen concentration Dv is greater than Rvmax, nitrogen can be inputted into the peak zone 103; when the detected oxygen concentration Dv is less than Rvmin, air is inputted into the peak zone 103; and when the detected oxygen concentration is within the adjustment range Rvmin-Rvmax, nitrogen and air are simultaneously inputted into the peak zone 103. The oxygen concentration in the peak zone 103 of the hearth 112 can thereby remain close to the required preset value Tv more precisely.

In this embodiment, the first valve apparatus 131, second valve apparatus 132, third valve apparatus 133 and fourth valve apparatus 134 are all flow control valves, and the first valve apparatus 131 and second valve apparatus 132 have higher precision requirements.

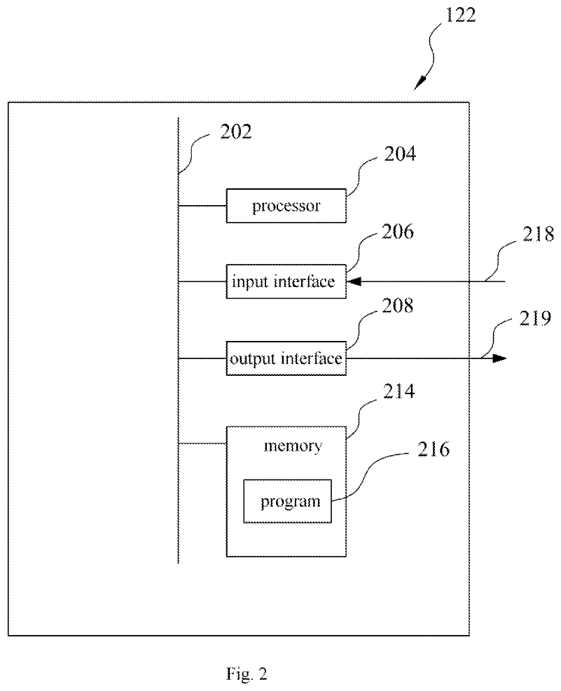

FIG. 2 is a simplified schematic drawing of an embodiment of the controller 122 in FIG. 1. The controller 122 comprises a bus 202, a processor 204, an input interface 206, an output interface 208 and a memory 214 having a control program 216. The processor 204, input interface 206, output interface 208 and memory 214 are in communicative connection via the bus 202, such that the processor 204 is able to control the operation of the input interface 206, output interface 208 and memory 214. The memory 214 is used for storing programs, instructions and data; the processor 204 reads programs, instructions and data from the memory 214, and can write data into the memory 214.

The input interface 206 receives signals and data via a connection 218, e.g. oxygen concentration signals sent by the oxygen detection apparatus 120, and various manually inputted parameters, etc. The output interface 208 sends signals and data via a connection 219, e.g. sends controls signals for adjusting the degree of opening to the valve apparatuses. Stored in the memory 214 are the control program 216, and preset data such as the preset value of oxygen concentration and the adjustment range. Various types of parameter may be set in advance in the process of production, and it is also possible for various types of parameter to be set by manual input or data import. The processor 204 acquires various signals, data, programs and instructions from the input interface 206 and the memory 214, performs corresponding processing, and produces an output via the output interface 208.

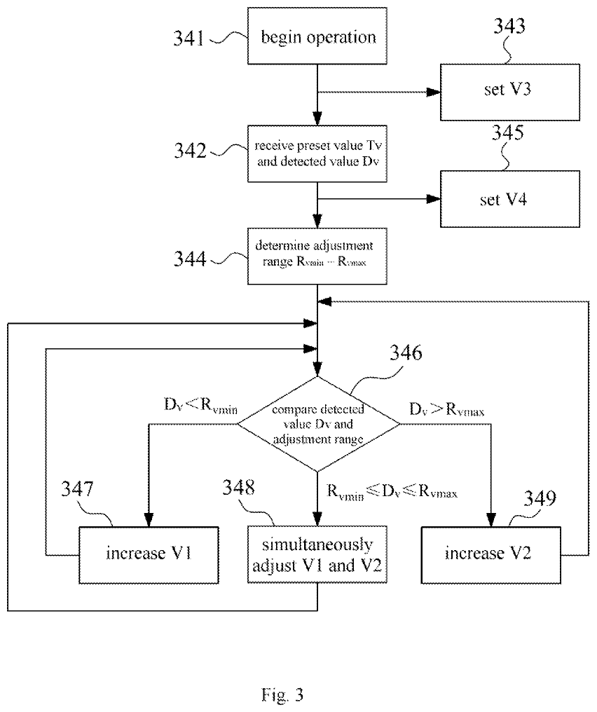

FIG. 3 shows a gas control method for the reflow oven shown in FIG. 1A. As shown in FIG. 3, the reflow oven 110 is configured to perform the following steps:

Step 341: the reflow oven 110 begins operation; step 342 and step 343 are then performed.

Step 342: the preset value Tv of oxygen concentration that is set according to specific soldering process requirements, and the detected value Dv of oxygen concentration that is actually detected by the oxygen detection apparatus 120, are received; step 344 and step 345 are then performed.

Step 343: the degree of opening V3 of the third valve apparatus 134 is set.

Step 344: the adjustment range Rvmin-Rvmax is determined, and stored in the memory 214 of the controller 122; step 346 is then performed.

Step 345: the degree of opening V4 of the fourth valve apparatus 134 is set.

Step 346: the detected value Dv and the adjustment range Rvmin-Rvmax are compared. When the detected value Dv<Rvmin, step 347 is performed. When the detected value Dv>Rvmax, step 349 is performed. When Rvmin≤detected value Dv≤Rvmax, step 348 is performed.

Step 347: the degree of opening V1 of the first valve apparatus 131 is increased, then the method returns to step 346.

Step 348: the degree of opening V1 of the first valve apparatus 131 and the degree of opening V2 of the second valve apparatus 132 are increased simultaneously, then the method returns to step 346.

Step 349: the degree of opening V2 of the second valve apparatus 132 is increased, then the method returns to step 346.

Thus, the gas control system 100 of the present application is able to adjust the oxygen concentration in the peak zone 103 of the hearth 112 of the reflow oven dynamically in real time. In step 347, step 348 and step 349, the specific values of the degrees of opening of the first valve apparatus 131 and second valve apparatus 132 are calculated according to a certain algorithm; as an example, the algorithm may be a PID algorithm (Proportion Integral Differential algorithm).

The gas control system and reflow oven of the present application first perform rough adjustment of gas in the reflow oven hearth by means of the third valve apparatus and fourth valve apparatus, such that the oxygen concentration in the hearth is substantially close to the preset value. The oxygen concentration in the peak zone of the hearth is then adjusted precisely by means of the first valve apparatus and second valve apparatus. Thus, even though the amount of oxygen in air entering the hearth is indeterminate, the oxygen concentration of the peak zone will not be affected, so the quality of circuit board soldering can be increased in a stable fashion.

Examples are used herein to disclose the present application, and one or more of these examples are illustrated in the drawings. Each example is provided for the purpose of explaining the present application, rather than limiting it. In fact, it will be obvious to those skilled in the art that various amendments and modifications may be made to the present application without departing from the scope or spirit of the present application. For example, an illustrated or described feature serving as part of one embodiment can be used together with another embodiment, to obtain a further embodiment. Thus, it is intended that the present application include amendments and modifications made within the scope of the attached claims and their equivalents.

1. A gas control system for a reflow oven, a hearth (112) of the reflow oven (110) containing a gas, the gas comprising oxygen and a working gas, and the hearth (112) comprising a preheating zone (101), a peak zone (103) and a cooling zone (105), characterized in that the gas control system (100) comprises:
an oxygen detection apparatus (120), the oxygen detection apparatus (120) being configured to detect the oxygen concentration in the peak zone (103);
a first valve apparatus (131), the first valve apparatus (131) being configured to fluidly connect a working gas source (140) to the peak zone (103) of the hearth (112) in a controllable fashion;
a second valve apparatus (132), the second valve apparatus (132) being configured to fluidly connect an air source (150) to the peak zone (103) of the hearth (112) in a controllable fashion; and
a controller (122), the controller (122) being in communicative connection with the oxygen detection apparatus (120), the first valve apparatus (131) and the second valve apparatus (132); and the controller (122) being configured to control the degree of opening of the first valve apparatus (131) and/or the second valve apparatus (132) when the oxygen concentration detected by the oxygen detection apparatus (120) does not satisfy a preset value, in order to enable the oxygen concentration in the peak zone (103) to satisfy the preset value by adjusting the flow rate of working gas and/or air inputted into the peak zone (103) of the hearth (112).

2. The gas control system as claimed in claim 1, characterized in that:
the gas control system (100) comprises a mixing duct (135), the mixing duct (135) comprising a first inlet (136), a second inlet (137) and at least one outlet (126, 127), the working gas source (140) being in fluid communication with the first inlet (136) via the first valve apparatus (131), the air source (150) being in fluid communication with the second inlet (137) via the second valve apparatus (132), and the at least one outlet (126, 127) being in fluid communication with the peak zone (103).

3. The gas control system as claimed in claim 1, characterized in that:
the peak zone (103) comprises three secondary peak zones (Z10, Z11, 212), the three secondary peak zones (Z10, Z11, Z12) comprising a middle secondary peak zone (Z11) located in the middle and two side secondary peak zones (Z10, Z12) located at two sides of the middle secondary peak zone (Z11);
the oxygen detection apparatus (12) is configured to detect the oxygen concentration in the middle secondary peak zone (Z11);
the at least one outlet (126, 127) comprises two outlets (126, 127), the two outlets (126, 127) being in fluid communication with the two side secondary peak zones (Z10, Z12) respectively.

4. The gas control system as claimed in claim 1, characterized by further comprising:
a third valve apparatus (133), the third valve apparatus (133) being configured to fluidly connect the working gas source (140) to the preheating zone (101) of the hearth (112);
the degree of opening of the third valve apparatus (133) remaining unchanged during operation of the reflow oven (110).

5. The gas control system as claimed in claim 4, characterized in that:
the preheating zone (101) comprises multiple secondary preheating zones (Z01, Z02 . . . Z09) and the working gas source (140) is controllably in fluid communication with the secondary preheating zone (Z02) that is second-furthest from the peak zone (103) via the third valve apparatus (133).

6. The gas control system as claimed in claim 4, characterized by further comprising:
a fourth valve apparatus (134), the fourth valve apparatus (134) being configured to fluidly connect the working gas source (140) to the cooling zone (105) of the hearth (112);
the degree of opening of the fourth valve apparatus (105) being determined according to the preset value.

7. The gas control system as claimed in claim 6, characterized in that:
the cooling zone (105) comprises multiple secondary cooling zones (C01, C02 C04), and the working gas source (140) is controllably in fluid communication with the secondary cooling zone (C03) that is second-furthest from the peak zone (103) via the fourth valve apparatus (134).

8. The gas control system as claimed in claim 1, characterized in that: the controller (122) is configured to:
determine an adjustment range according to the preset value of oxygen concentration;
increase the degree of opening of the first valve apparatus (131) when the oxygen concentration detected by the oxygen detection apparatus (120) is greater than the maximum value of the adjustment range, to enable the oxygen concentration to reach the adjustment range by increasing the flow rate of working gas inputted into the peak zone (103) of the hearth (112);
increase the degree of opening of the second valve apparatus (132) when the oxygen concentration detected by the oxygen detection apparatus (120) is less than the minimum value of the adjustment range, to enable the oxygen concentration to reach the adjustment range by increasing the flow rate of oxygen inputted into the peak zone (103) of the hearth (112);
adjust the degrees of opening of the first valve apparatus (131) and the second valve apparatus (132) when the oxygen concentration detected by the oxygen detection apparatus (120) is within the adjustment range, so that the oxygen concentration in the peak zone (103) satisfies the preset value.

9. The gas control system as claimed in claim 6, characterized in that:
the first valve apparatus (131), the second valve apparatus (132), the third valve apparatus (133) and the fourth valve apparatus (134) are flow control valves.

10. A reflow oven, characterized by comprising:
a hearth (112), the hearth (112) comprising a preheating zone (101), a peak zone (103) and a cooling zone (105), and the hearth (112) containing a gas, the gas comprising oxygen and a working gas; and
the gas control system (100) as claimed in claim 1.
